(19) United States
(12) Patent Application Publication
(10) Pub. No.: US 2016/0240414 A1
(43) Pub. Date: Aug. 18, 2016

(54) Chuck for Suction and Holding a Wafer

(71) Applicant: SUSS MICROTEC LITHOGRAPHY GMBH, Garching (DE)

(72) Inventors: Matthias Conradi, Garching (DE); Sven Hansen, Garching (DE)

(73) Assignee: Suss Microtec Lithography GMBH, Garching (DE)

(21) Appl. No.: 15/024,160

(22) PCT Filed: Sep. 26, 2013
(86) PCT No.: PCT/EP2013/070092

§ 371 Date: Mar. 24, 2016

(51) Int. Cl. H01L 21/67; H01L 21/683

(52) U.S. Cl. CPC H01L 21/67288; H01L 21/6838

(57) ABSTRACT

The invention relates to a chuck and a method for suction and holding a wafer by said chuck, wherein the chuck comprises: a flat top face being subdivided into several suction segments, wherein the suction segments are each configured for suctioning a fluid; and a bottom face. The method comprises the steps: bringing, within a fluid, wafer and top face of the chuck into vicinity such that two or more of the suction segments are covered, at least loosely covered, by the wafer; choosing, from the suction segments not yet been activated, a suction segment having a minimal distance to the wafer; activating the suction segment chosen in the previous step; once the wafer in the area of the last-activated suction segment tightly touches the top face of the chuck and as long as at least one suction segment is not yet activated: repeating the foregoing steps.

The present invention relates to a chuck for suction and holding a wafer, and a method for suction and holding a wafer by said chuck. In particular, the present invention relates to a chuck having several suction segments, wherein each of the suction segments is separately activatable, and a method for using said chuck, wherein the order of activating the suction segments is based on choosing a suction segment having a minimal distance to the wafer.

Chuck devices are used for holding a substrate or a wafer, while the wafer is being processed during fabrication of an integrated circuit (IC) or a similar micro device. Wafers typically have the form of a slice. Often, e.g. in case the thickness of a wafer is rather low, but also for other reasons such as the manufacturing process of the wafer, it happens that the wafer either itself is not shaped as a fully planer slice, and/or that the wafer becomes curved or folded when being held by the chuck. Then, the wafer additionally may become skewed or distorted.

For sucking arced and/or distorted wafers, gaskets have been used so far. These gaskets can be located at the edge of the wafer/chuck, as well as on various positions of the support plate of the chuck (vacuum cups). Thereby, the gaskets can be assigned to different vacuum circuits. Those vacuum circuits (chuck/vacuum cup) can be switched or activated at a time or consecutively.

In WO 2006/072453, an end effector (chuck) with at least two vacuum circuits is described. Such assembly can be used for sucking distorted wafers, in particular thin and ultrathin wafers. According to WO 2006/072 453, the end effectors are constructed as plates made of porous material, in particular porous sintered materials.

However, suction by means of gaskets or lip seals has disadvantages. For example, the gaskets or lip seals may not be heat resistant/temperature resistant and/or lack solvent resistance. Furthermore, the gaskets or seal lips may produce particles. Further, because of the inherent coarseness of the surface of a porous, e.g. sintered, material, it is often difficult to clean such end effectors, which may also reduce the durability of the end effector. Moreover, as the wafer is pressed against the surface of the end effector while being held by the end effector, the coarse surface structure of the end effector may unduly affect the surface structure of the wafer. Moreover, any two vacuum circuits of the end effector described in WO 2006/072 453 are pneumatically separated from each other. Consequently, for each of the vacuum circuits, an extra vacuum connection has to be provided. So, if for example eight vacuum circuits are used, the vacuum supply to the eight corresponding vacuum connections must be managed which may be difficult to handle.

It is an object of the present invention to provide a chuck and a method for using said chuck, which allow for sucking a wafer such that distortions, curvatures, wrinkles, foldings, and/or skewness is avoided when the wafer is being held by the chuck. A further objection of the invention is to avoid the above described disadvantages of using gaskets and/or seal lips and/or the use of an end effector having a porous, e.g. sintered, surface.

These objections are solved by the chuck and the method with the features according to the present claims set.

For sucking a skewed/distorted wafer, it is advantageous to suck the wafer at first at those positions, where one of several suction segments of the chuck is most tightly sealed by (a portion of) the wafer. In other words: provided the chuck is divided in several vacuum areas or suction segments, the wafer has to be sucked at first at positions, where the lowest pressure loss occurs. Usually, these positions are areas, where the wafer covers the respective suction segment as completely as possible.

These suction segments may have a very smooth surface, e.g. with a flatness of 0.002 mm or even better, which allow facilitating the cleaning, an improved durability and improved contact with the attached wafer.

In case the skewness/distortion of the wafer is defined by the preceding fabrication process of the wafer, e.g. if the wafers to be held are convex, the choice of the suction segments and/or the shape of which can be chosen such that at positions, where the wafer rests on the chuck, a maximum volume flow is provided.

Throughout the following, the expression “supply of vacuum” denotes that fluid is evacuated from a certain area. For example, supplying a suction segment with vacuum means that fluid, e.g. air or liquid, is evacuated from the area above the top face of the chuck in the area of the suction segments. This corresponds to establishing a low pressure in the respective area.

As “low pressure” means that the pressure is less than a reference pressure, e.g. the pressure of the fluid in the environment of the chuck, the assigned value is negative (e.g. −1 bar). In order to avoid confusion, in the following text it will be referred to the absolute value of low pressure, which is then always a positive value (e.g. |−1| bar=1 bar), and also comparative terms (“higher”, “larger”, “less than”, etc.) refer to the absolute values. For example, the formulation that a first low pressure is “higher” than a second low pressure denotes that the absolute value of the first low pressure is greater than the absolute value of the second low pressure.

Further, the term “fluid” is used as a generic expression referring to both, gases (such as air) and liquids.

The term “main vacuum” refers to a low pressure strong enough to suck the wafer towards and hold the wafer on the top face of the chuck.

The term “auxiliary vacuum” refers to a vacuum weaker than a main vacuum, wherein the auxiliary vacuum is only used for measurements as to the distance of certain areas of the wafer to the top face of the chuck, and wherein the auxiliary vacuum is not adapted for sucking the wafer towards the top face of the chuck/the respective suction segment of the chuck.

The expression “activating a suction segment” denotes that said suction segment is supplied with main vacuum (cf. definition of “supply of vacuum” above). In particular, the term “activating” refers to a vacuum supply such that a wafer can be sucked by the caused volume flow of fluid. That is to say, fluid flows caused by an “auxiliary vacuum” do not “activate” a suction segment, as an auxiliary vacuum is only meant for measuring purposes and is typically not strong enough for sucking the wafer.

For the term “distance” between wafer and suction segment, several definitions are equally possible. For example, the mathematical standard definition of the distance between two objects can be used: then, the distance is given by the minimum element of the set of all distances between any two points, wherein one of the points geometrically belongs to the wafer, and the other point belongs to the suction segment of the chuck. Another definition that can be used here likewise is as follows, provided the surface (facing the wafer) of the suction segment is geometrically shaped as a plane: Consider the set of each of the distances between a point of the surface of the suction segment and a point of the surface of the wafer, wherein both of said points are located on a straight line perpendicular to the surface of the suction segment. Then, the distance between the wafer and the suction segment may be defined as the average value of all elements of the set, e.g. the arithmetic mean of the set. (Please note that this definition also applies when the wafer does not completely cover the suction segment.) Of course, any other suitable definition of the distance between the wafer and the suction segment can be used likewise. Throughout the following, it may be assumed that the distance between the wafer and the suction segment can be at least approximately determined by measuring the low pressure (auxiliary vacuum) of the fluid located between a suction segment and the wafer.

One aspect of the invention relates to a chuck for suction and holding a wafer, comprising a flat top face being subdivided into several suction segments, wherein the suction segments are each configured for suctioning a fluid; and a bottom face, wherein: the top face is configured for being brought, within a fluid, into vicinity with a wafer such that two or more of the suction segments are covered, at least loosely covered, by the wafer; and each of the suction segments is separately activatable.

The formulation that a suction segment is “covered” by the wafer denotes here and in the following that the wafer (or a part of which) is located in an area on the side of the top face of the suction segment, where the wafer (or a part of which) is attracted by the suction segment when the suction segment is activated. Thus, the formulation does not necessarily denote that the wafer (or a respective part of which) touches the suction segment. However, when the wafer (or a respective part of which) touches the suction segment, the suction segment is covered by the wafer.

The term “loosely covered” denotes that a certain suction segment is “covered” by the wafer, wherein the wafer, however, does not touch the top face of the suction segment.

The formulation “bringing the top face of the chuck into vicinity with the wafer” denotes any movements of the top face relative to the wafer such that two or more of the suction segments become covered, or at least loosely covered, by the wafer. In principal, any position and/or orientation of the wafer relative to the top surface of the chuck can be chosen during the approach. However, it is preferred that the top surface of the chuck approaches the wafer such that for most points of the wafer, the respective tangential vectors deviate only a small amount, e.g. less than 30 degrees, from an orientation parallel to the top face of the chuck.

Preferably, the top face may relate to the surface of a solid material such as a metal or alloys of different metals or a polymer. In particular, said solid material may not relate to a porous material such as, e.g., a sintered material.

The chuck may further comprise: a means, preferably a throttle, configured for supplying each of the suction segments with an auxiliary vacuum; a means, preferably comprising at least one pressure detection means or at least one flow rate detection means, configured for measuring, at any one of the suction segments, the low pressure or the flow rate of the volume flow of fluid sucked in by the respective suction segment when being supplied with the auxiliary vacuum; and a means, preferably a mechanical and/or electric means connected to each of said means configured for measuring the low pressure or the flow rate, configured for determining at which of the suction segments, when supplied with the auxiliary vacuum, is measured a maximum absolute value of the low pressure or a minimum volume flow of the fluid.

Here, the electric means may be, e.g., an electronic circuit or an integrated circuit (IC) as well as a microcontroller, a computer, etc.

In a preferred embodiment of the chuck, the top face of the chuck is a disc; an inner suction segment is arranged around the center point of the top face; and further suction segments are arranged as rings around the inner suction segment; and wherein preferably each of the suction segments is separated from the other suction segments.

In one embodiment of the chuck, each of the suction segments comprises a system of interconnected grooves arranged on the top face of the chuck, and wherein preferably each system of interconnected grooves comprises one or more grooves shaped as concentric circles around the center point of the top face.

In one embodiment of the chuck, the several suction segments are arranged on the top face such that a virtual spiral-shaped path originated in a point within one of the suction segments and looping to the edge of the top face proceeds on the top face, wherein the path enters and/or leaves any one of the suction segments one and only one time.

In a preferred embodiment of the chuck, each suction segment is connected to a main vacuum distribution means being arranged at the bottom face of the chuck and configured for supplying each of the suction segments with vacuum; and the supply of each of the suction segments, possibly with the exception of one suction segment, is controllable by a valve.

In one embodiment of the chuck, the main vacuum supply means comprises a main vacuum channel having an inlet configured for being supplied with vacuum (main vacuum supplied via said inlet may also be referred to as “first chuck vacuum” in the following); each of the suction segments is connected to the main vacuum channel by a side conduit having a junction to the main vacuum channel; between any two adjacent junctions, a valve is arranged inside the main vacuum channel such that the main vacuum channel exhibits several sections separated by said valves; and the side conduits are arranged such that any two adjacent sections of the main vacuum channel are connected to neighbored suction segments.

In a preferred embodiment of the chuck, each of said valves is a check valve, for example one of a ball check valve, a diaphragm check valve, a swing check valve, a tilting disc check valve, a stop check valve, a lift check valve, an in-line check valve, or a duckbill valve; each of the check valves is configured such that it automatically opens if the absolute value of the low pressure in the section next to the check valve in the direction towards the inlet of the main vacuum channel is equal to or greater than a predefined value; and preferably each of the check valves is configured such that it opens only if the absolute value of the low pressure in the section next to the check valve in the direction towards the inlet of the main vacuum channel is value corresponding to a state, wherein the wafer tightly touches the suction segment connected to the section next to the check valve in the direction towards the inlet.

Another aspect of the invention relates to a method for suction and holding a wafer by a chuck, wherein the chuck comprises: a flat top face being subdivided into several suction segments, wherein the suction segments are each configured for suctioning a fluid; and a bottom face. The method comprises the steps:
(9a) bringing, within a fluid, wafer and top face of the chuck into vicinity such that two or more of the suction segments are covered, at least loosely covered, by the wafer;
(9b) choosing, from the suction segments not yet been activated, a suction segment having a minimal distance to the wafer;
(9c) activating the suction segment chosen in step (9b);
(9d) once the wafer in the area of the last-activated suction segment tightly touches the top face of the chuck and as long as at least one suction segment is not yet activated:
   repeating steps (9b) to (9d).

As to step (9b): In case there are several suction segments having a minimal distance to the wafer, “choosing” comprises a decision, which one of the several suction segments having a minimal distance to the wafer shall be chosen. For example, this algorithm may comprise a decision step such that from several suction segments having a minimal distance to the wafer, the one located closest to the centre point of the top surface of the chuck is chosen. Alternatively, the algorithm may comprise a step, wherein one of the suction segments having a minimal distance to the wafer is chosen randomly.

In a preferred embodiment of the method, step (9b) of choosing a suction segment having a minimal distance to the wafer comprises the steps of:
(10a) measuring the distance of each of the suction segments to the surface of the wafer facing the respective suction segment;
(10b) determining, from the suction segments not yet activated, a suction segment having a minimal distance to the wafer.

In one embodiment of the method, step (10a) of measuring the distance comprises the steps of:
(11a) supplying, preferably by a throttle, each of the suction segments not yet been activated with an auxiliary vacuum;
(11b) measuring, for each of the suction segments supplied with the auxiliary vacuum in step (11a), the low pressure or the flow rate of the volume flow of the fluid sucked in, preferably by a pressure detection means or a flow rate detection means; and
   step (10b) of determining a minimal distance comprises the step of:
(11c) determining, preferably by a mechanical and/or electric means connected to each of the pressure detection means or each of the flow rate detection means, at which of the suction segments supplied with the auxiliary vacuum is measured a maximum absolute value of the low pressure or a minimum volume flow of the fluid.

Here, the electric means may be, e.g., an electronic circuit or an integrated circuit (IC) as well as a microcontroller, a computer, etc.

In an alternative embodiment of the method, the sequence of suction segments chosen in step (9b) is predefined according to a known shape of the wafer.

In a preferred embodiment of the method, the top face of the chuck is a disc; an inner suction segment is arranged around the center point of the top face; further suction segments are arranged as rings around the inner suction segment. Preferably, each of the suction segments is separated from the other suction segments.

In one embodiment of the method, each of the suction segments comprises a system of interconnected grooves arranged on the top face of the chuck. Preferably, each system of interconnected grooves comprises one or more grooves shaped as concentric circles around the center point of the top face.

In one embodiment of the method, the several suction segments are arranged on the top face such that a virtual spiral-shaped path originated in a point within one of the suction segments and looping to the edge of the top face proceeds on the top face, wherein the path enters and/or leaves any one of the suction segments one and only one time; and the sequence of suction segments chosen in step (9b) follows the virtual spiral-shaped path, wherein the first suction segment is the suction segment with the origin of the virtual spiral-shaped path.

Preferably, each suction segment is connected to a main vacuum distribution means being arranged at the bottom face of the chuck and configured for supplying each of the suction segments with vacuum; and the supply of each of the suction segments, possibly with the exception of one suction segment, is controllable by a valve. Then, the method may comprise the step of:
(16a) supplying the main vacuum distribution means with vacuum, this step being started before or together with step (9c) and executed as long as the wafer is to be held by the chuck; and
   wherein step (9c) of activating a suction segment comprises the step of:
(16b) if the suction segment is controllable by a valve: opening the valve being configured to control the respective suction segment,
   otherwise: starting step (16a).

In one embodiment of the method, the main vacuum supply means comprises a main vacuum channel having an inlet configured for being supplied with vacuum; each of the suction segments is connected to the main vacuum channel by a side conduit having a junction to the main vacuum channel; between any two adjacent junctions, a valve is arranged inside the main vacuum channel such that the main vacuum channel exhibits several sections separated by said valves; the side conduits are arranged such that any two adjacent sections of the main vacuum channel are connected to neighbored suction segments; and step (9b) of choosing a suction segment comprises:
if step (9b) is executed the first time during the performance of the method: choosing the suction segment connected to the section of the of main vacuum channel next to the inlet;
otherwise: choosing the suction segment connected to the section of the main vacuum channel next to the section connected to the suction segment previously chosen in step (9b).

Preferably, each of said valves is a check valve, for example one of a ball check valve, a diaphragm check valve, a swing check valve, a tilting disc check valve, a stop check valve, a lift check valve, an in-line check valve, or a duckbill valve; wherein each of the check valves is configured such that it automatically opens if the absolute value of the low pressure in the section next to the check valve in the direction towards the inlet of the main vacuum channel is equal to or greater than a predefined value; and wherein preferably each of the check valves is configured such that it opens only if the absolute value of the low pressure in the section next to the check valve in the direction towards the inlet of the main vacuum channel is value corresponding to a state, wherein the wafer tightly touches the suction segment connected to the section next to the check valve in the direction towards the inlet.

In a preferred embodiment, the method comprises the further step of:
(19a) upon the wafer completely being held by the chuck: supplying the main vacuum channel with an additional vacuum (also referred to as “second chuck vacuum”) from the side opposite to the inlet.

Other aspects, features, and advantages will be apparent from the summary above, as well as from the description that follows, including the figures and the claims.

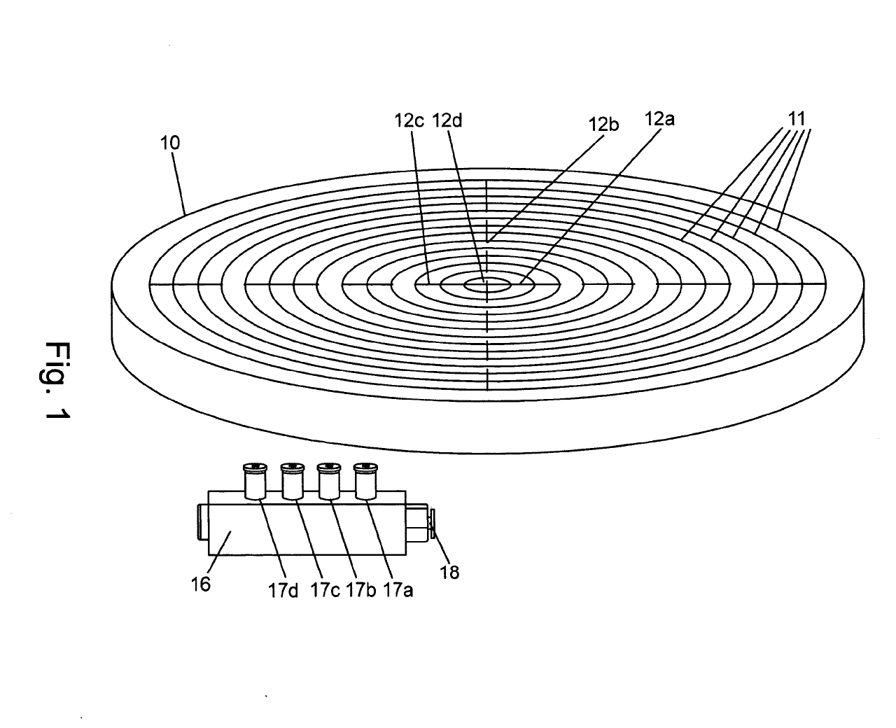

FIG. 1: Chuck with vacuum distributor

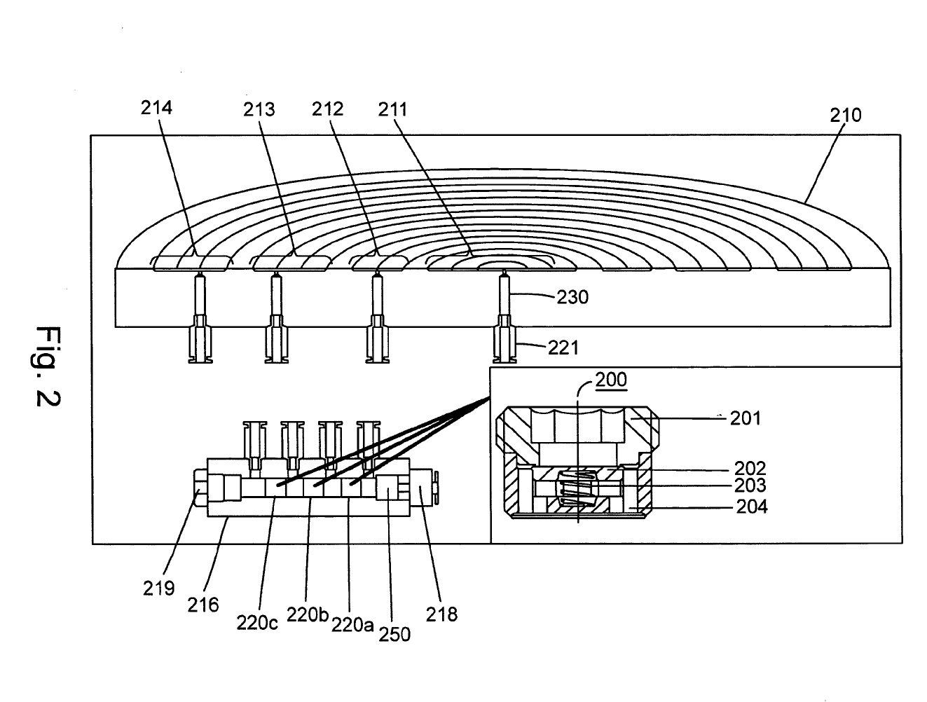

FIG. 2: Functional principle

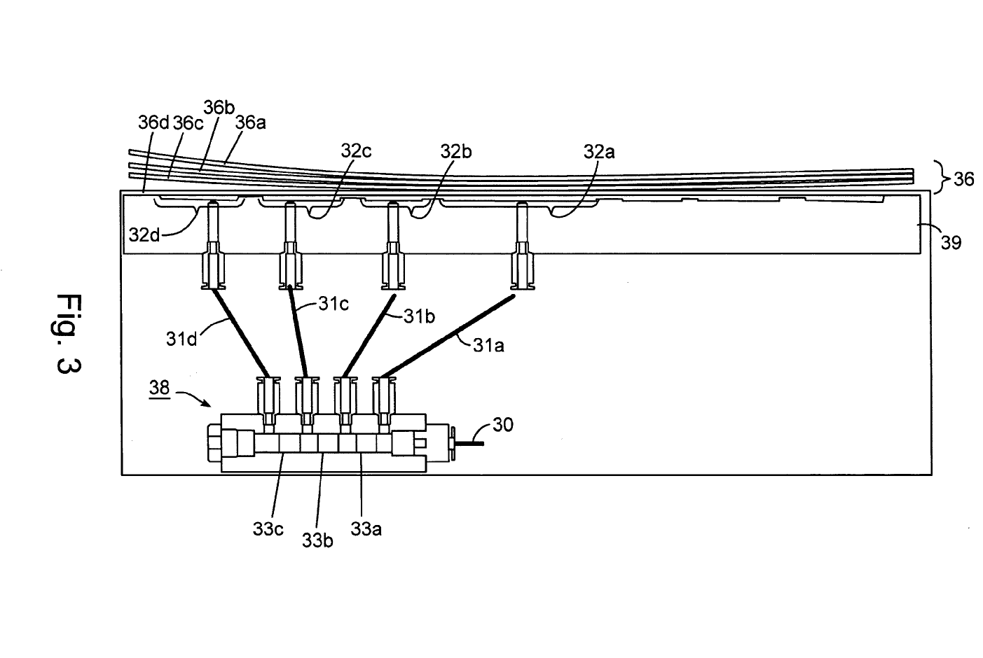

FIG. 3: Procedure of subsequently activating suction segments and thus generating a maximal volume flow rate in order to provide a sufficiently strong pressure on the wafer

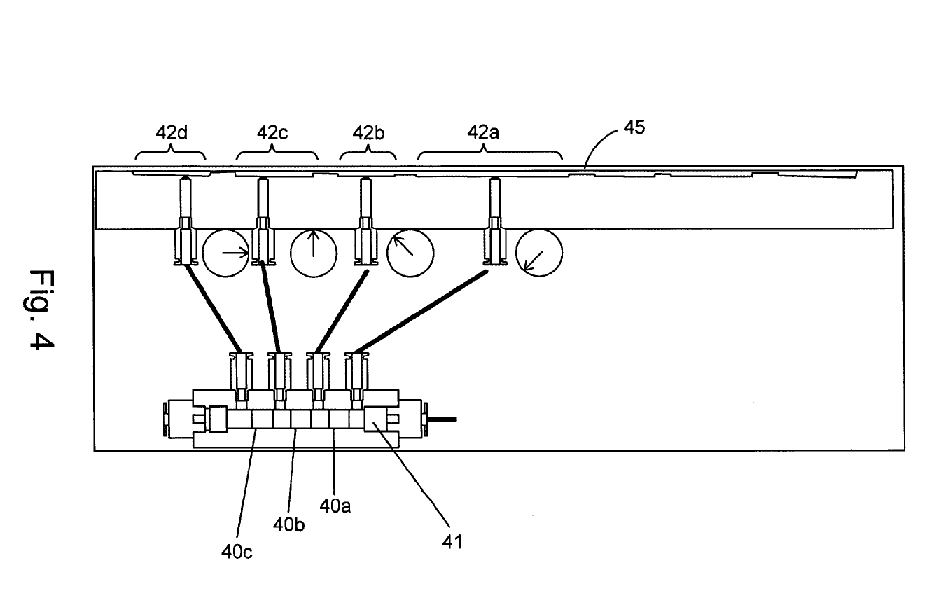

FIG. 4: Illustration of the pressure decay over different suction segments

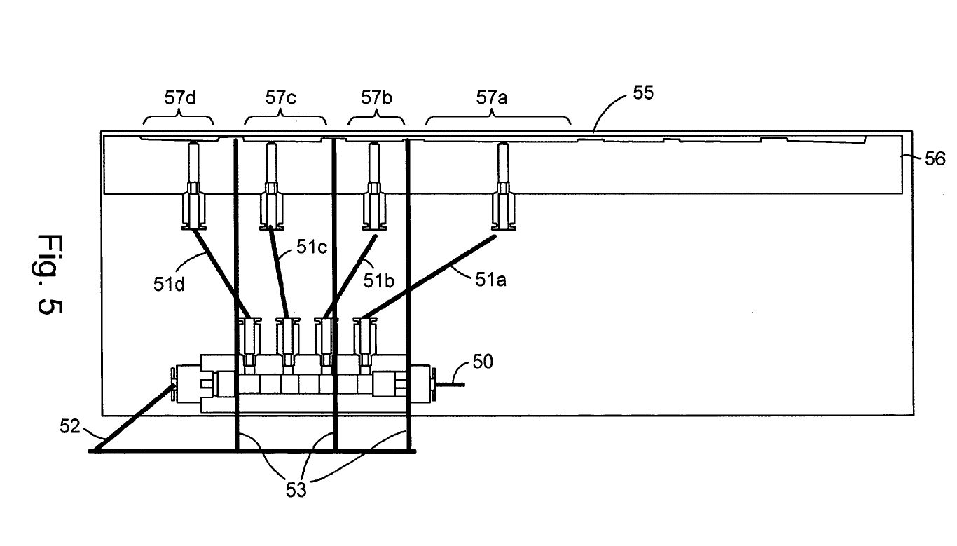

FIG. 5: Avoiding a pressure decay by application of an additional vacuum

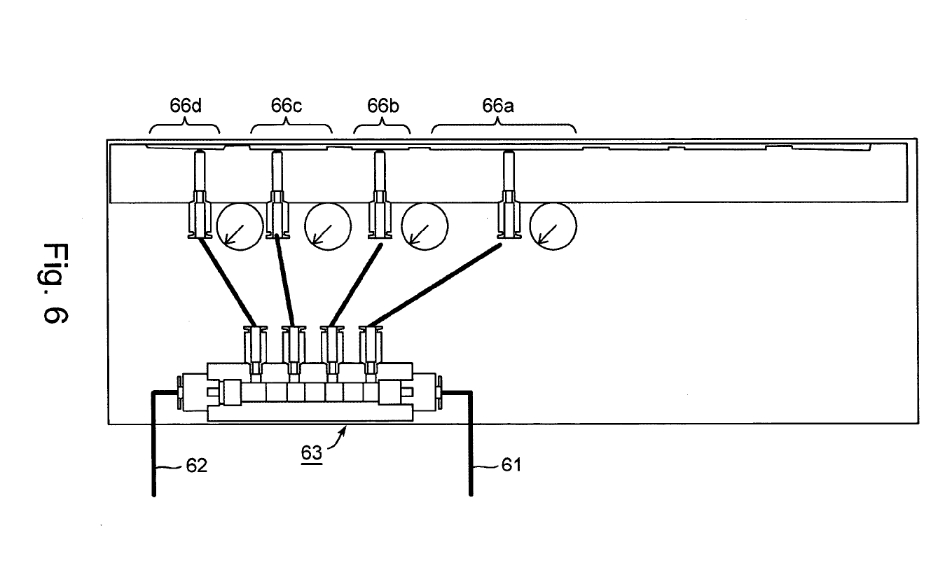

FIG. 6: Illustration of the constant pressure obtained by an additional vacuum

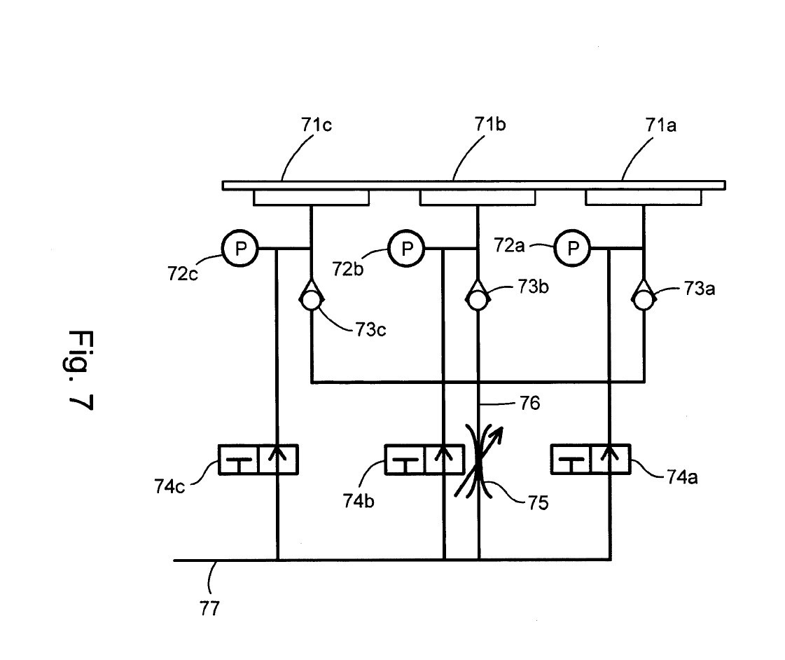

FIG. 7: Sketch of a circuit for measuring the distance between the wafer and the suction segments

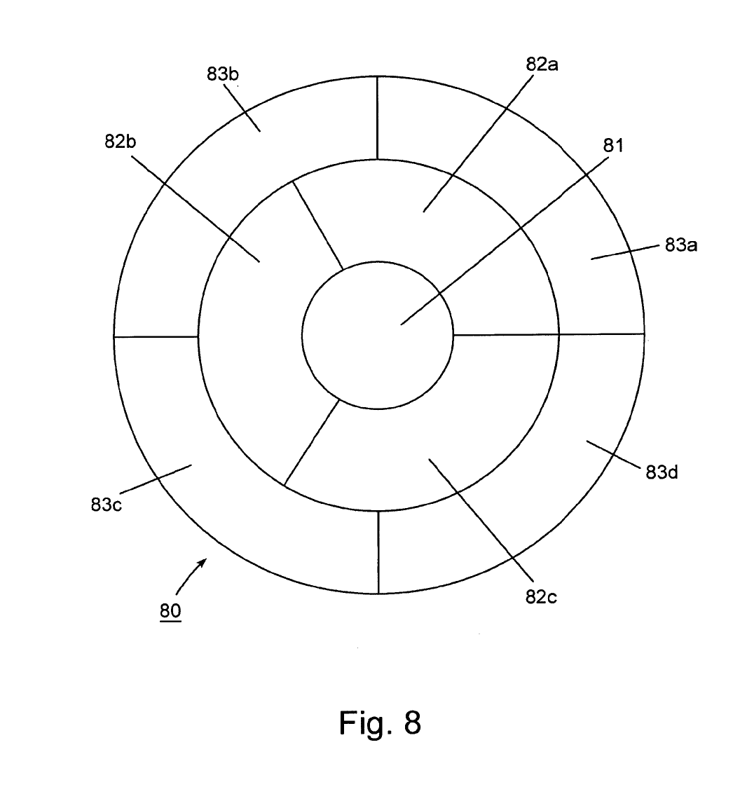

FIG. 8: Possible partitioning of a top face of a chuck into a plurality of suction segments

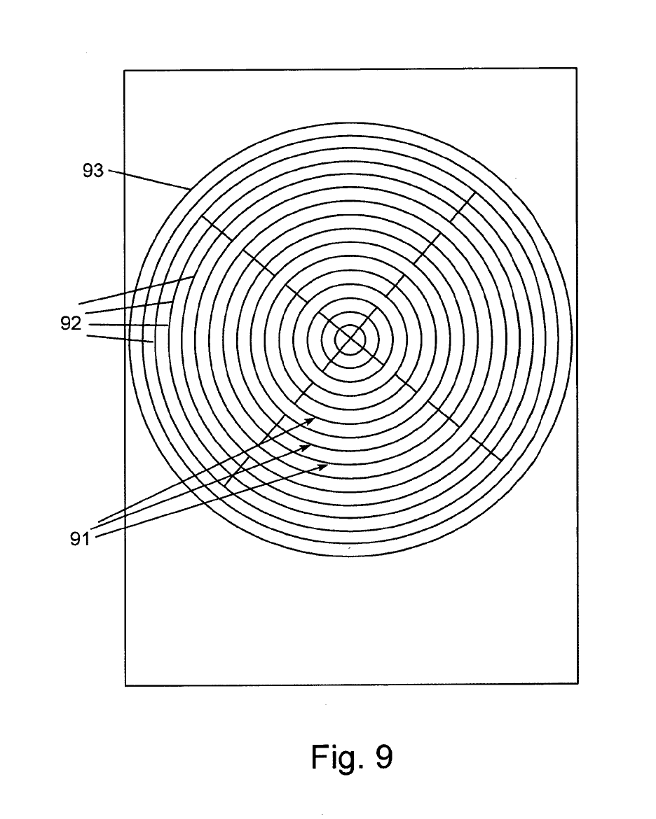

FIG. 9: Photograph of an embodiment of the chuck (top face)

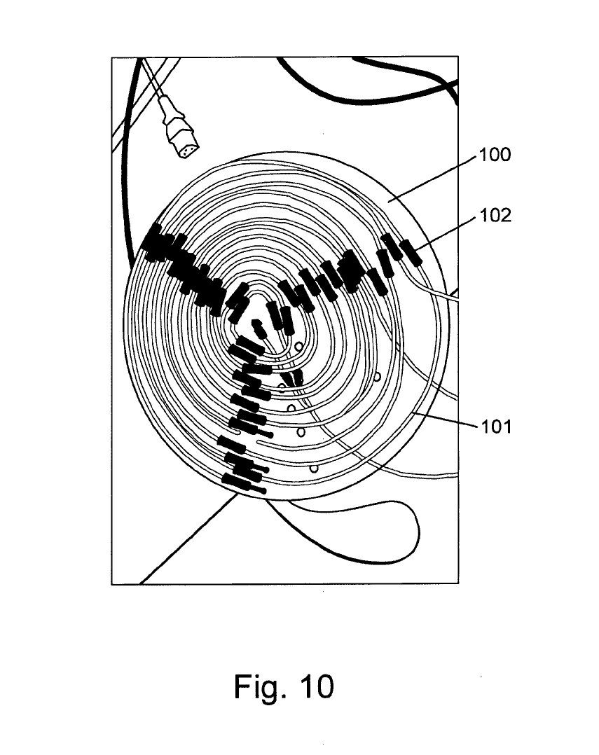

FIG. 10: Photograph of an embodiment of the chuck (bottom face with main vacuum channel and check valves)

### CASCADE CONNECTION WITH CHECK VALVES

In order to achieve an as possible high volume flow in each of the suction segments, said suction segments can be separated by check valves, for example ball check valves. In one embodiment of the chuck according to the invention, the chuck comprises a main vacuum channel having an inlet configured for being supplied with vacuum (low pressure). The main vacuum channel is then subdivided into several portions, wherein between any two neighbored portions, a check valve is installed. For example, N−1 check valves are typically required to divide the main vacuum channel into N portions. Then, via a side conduit, each of the portions is connected to one of the suction segments. This assembly is referred to as “cascade connection” throughout this document.

In the following, the numbering of the check valves and the portions of the main channel shall—for the sake of clarity and simplicity—correspond to the position relative to the inlet: the first portion of the main vacuum channel is directly connected to the inlet without a check valve in between. Then, the first check valve separated the first portion from the second portion of the main vacuum channel. The second portion is then separated from the third portion by the second check valve etc. Further, the numbering of a certain suction segments shall correspond to the numbering of the portion to which the suction segment is connected via the side conduit.

In order to suck a wafer by the chuck, the cascade connection is supplied with vacuum via the inlet. Due to the first check valve being still closed, the “complete” fluidic volume flow (e.g. air flow) occurs from the first suction segment via the respective side conduit and the first portion of the main vacuum channel to the vacuum supply connected to the inlet. This causes the wafer to be sucked into the direction of the chuck in the area of the first suction segment. Finally, the wafer tightly seals the first suction segment, i.e., is completely sucked in the area of the first suction segment.

Ideally, the (first) check valve only opens, when the wafer in the first suction segment has been sucked completely. Subsequently, the “complete” volume flow occurs at the second suction segment. Then, only when the wafer is fixed at the second suction segment and seals it completely, the next suction segment will be activated by an opening of the next check valve. This procedure (automatically) repeats until the last check valve is open and the “full” volume flow occurs at the last suction segment. Finally, the wafer is sucked and held by each of the suction segments (provided that the size of the wafer is large enough to cover each of the suction segments).

As any check valve causes a pressure loss, it is possible that the vacuum (low pressure, measured by the absolute value of the low pressure) in the last suction segment is relatively low in comparison to the vacuum (low pressure) of the first suction segment. In order to compensate for that, the last suction segment can be supplied with an additional vacuum, after the wafer is completely sucked and held by the chuck.

### Sequence of Activating Suction Segments

As already discussed above, it is advantageous to suck the wafer at first in the area of the suction segment being most tightly covered by (a portion of) the wafer. In one embodiment of the chuck according to the invention, an auxiliary vacuum is used in order to determine this area.

For example, the following assembly may be considered. A main vacuum channel, the channel having an inlet configured for supplying the channel with vacuum, splits into several branches, wherein each of the branches is connected to a suction segment arranged on a top face of the chuck. Each of the branches comprises a switch (a valve) configured for switching on and off the connection of the respective suction segment to the main vacuum channel. Thus, each of the suction segments can be independently activated/deactivated by switching on or off the switch at the corresponding branch, and thus establishing or cutting the vacuum supply of the suction segment with vacuum (low pressure) from the main vacuum channel. Further, each of the suction segments is connected to a channel system configured for supplying the suction segments with an auxiliary vacuum. For example, the auxiliary vacuum channel system is connected to the main vacuum channel and comprises a throttle.

Then, in comparison with the volume flow (e.g. air flow) caused by the main vacuum, the volume flow of the auxiliary vacuum is reduced by means of the throttle. The auxiliary vacuum is connected to the plurality of suction segments via check valves and pressure gauges. Then, the more a suction segment is covered by a wafers, the more the pressure decreases (or in other words: the absolute value of the low pressure increases) at this suction segment. At the suction segment being sealed by the wafer most tightly in comparison to the remaining suction segments, the (absolute value of the) low pressure will have a maximum.

Once the suction segment being sealed by the wafer most tightly is determined, the corresponding check valve will be activated and the wafer becomes partially sucked in this area until the wafer tightly seals the respective suction segment.

Then, for each of the remaining suction segments, the (low) pressures of the auxiliary vacuum are measured and the suction element where the (absolute value of the) low pressure has a maximum is determined again. This suction segment will be activated by opening the respective switch so as to supply vacuum from the main vacuum channel to the suction segment. The wafer will then be sucked in the area of this suction segment, and the procedure may be repeated until each of the suction segments are activated and the wafer is sucked completely.

### Spiral Suction

If wafers exhibit, e.g. due to preceding fabrication processes, always the same or similar distortions, the shape of the suction segments and/or the sequence of supplying the suction segments with vacuum in the chuck can be adapted to this distortion or deformation.

For example, in case of concave wafers, it may be of advantage to suck a wafer from the inside of the top face of the chuck outwards to the edge of the top face.

This may be realized by a high volume vacuum channel arranged beneath a top face of a chuck and leading spirally from a centre point to the edge of the top face of the chuck. Further, vacuum grooves are arranged on the top face of the chuck. The vacuum grooves or various systems (groups) of vacuum grooves are separated from each other. Additionally, the chuck may be subdivided in different suction areas or suction segments. This is necessary for sucking highly deformed/distorted wafers.

### Combination of Cascade Connection and Spiral Section

The spiral section can be combined with the cascade connection described above. This allows for a reduction of vacuum check valves. For example, it is then possible to suck highly distorted wafers with only two check valves instead of three or more check valves.

For example, this may be in particular advantageous in order to save check valves for economical reasons and/or because the software controlling the chuck has to be adapted to any configuration, i.e. alignment of channels, check valves etc., of said chuck.

FIG. 1 shows two parts of one embodiment of the chuck according to invention. The top face 10 of the chuck is formed as a disc. On the disc, several grooves are arranged. Circular grooves 11 are arranged around the centre point of the top face of the chuck such that they form a system of concentric circles. Furthermore, grooves in radial direction (relative to the centre point of the top face 10) are arranged on the top face 10 of the chuck. For example, radially oriented grooves 12a, 12b, 12c, and 12d proceed astrally from the centre point of the top face 10 up to the third circular groove (counted from the centre point to the edge). Thus, radial grooves 12a to 12d connect the system of the three inner circular grooves. Likewise, the fourth to the seventh circular grooves are interconnected by grooves in radial direction, wherein these grooves, however, are not connected to the system of the three innermost circular grooves and the radial grooves 12a to 12d. Also, the eighth to the eleventh circular grooves are interconnected by radial grooves. Finally, the twelfth up to the fifteenth circular grooves are interconnected by radially oriented grooves. This way, there are four independent systems of grooves (i.e. systems not being interconnected) that are arranged on the top face of the chuck. Each of these systems can be considered a suction segment, which is activatable independently.

FIG. 1 also shows a housing 16 covering a cascade connection. The housing 16 comprises an inlet 18 configured for being connected to a main vacuum supply and four outlets 17a, 17b, 17c, and 17d, each of the outlets being configured for being connected to one of the above described systems of grooves arranged on the top face of the chuck.

FIG. 2 shows a cut through the top face of the chuck as well as a cut through the housing 16 of FIG. 1. The housing 216 comprises a main vacuum channel 250 through which the fluid can be conducted. Fluid can be evacuated from this channel 250 via the inlet 218. Within the channel 250, three check valves 220a, 220b, and 220c are provided. The three check valves 220a, 220b, and 220c divide the channel 250 in four portions. Each of the portions is connected to one of the outlets 217a to 217d via a side conduit. A further inlet 219 is provided at the side of the channel 250 located opposite to the inlet 218. The further inlet 219 allows additionally supplying the main vacuum channel 250 with an additional vacuum.

A cut through an example check valve 200 is shown in the inset of FIG. 2. The check valve 200 comprises a housing 201. Within the housing 201, a piston or a plunger 202 is arranged, which is held by a spiral spring 203 in a position so as to keep the check valve 200 closed. However, when the pressure on the side of the plunger 202 opposite to the spiral spring 203 exceeds the pressure exerted from the spring 203 onto the plunger 202, the check valve 200 opens, and fluid can pass the check valve 200.

On the top face 210 of the chuck, four systems 211, 212, 213, 214 of grooves are arranged. These systems of grooves can be activated independently by supplying vacuum via the inlets 221, 222, 223, and 224. Each of these inlets 221 to 224 is connected via a conduit to one of the groups of grooves. For example, the inlet 221 is connected via the conduit 230 to the system of grooves 211 comprising the three innermost circular grooves. Then, the innermost system of grooves forming a first suction segment of the chuck may be connected via the inlet 221 and the outlet 217a to that portion of the channel 250 of the cascade connection that is located closest to the inlet 218. Further, the second system of grooves 212 (counted from the centre of the top face 210 to the edge) may be connected via the inlet 222 and the outlet 217b to that portion of the channel 250 that is separated by only one check valve 220a from the inlet 218. Likewise, the third system of grooves 213 may be connected to the third portion of the channel 250, and finally the outer (fourth) system of grooves 214 may be connected via the inlet 224 and the outlet 217d to a portion of the channel 250 that is separated by all of the check valves from the inlet 218.

Due to this construction, no check valve would open when a main vacuum is supplied via inlet 218, as long as fluid can be sucked from the inner suction segment 211. However, when the inner suction segment 211 is sealed tightly by a wafer (wafer not shown), then the first check valve 220a would open, as long as the second suction segment 212 is not tightly covered by a portion of the wafer, and thus a volume flow occurs at the second suction segment 212. The second check valve 220b, however, is still in a closed state. Then, the “full” vacuum is provided to the second suction segment 212, exerting the strongest (low) pressure on the wafer in the area of the second suction segment 212. Only after the second suction segment 212 has been tightly sealed by (a portion of) the wafer, the second check valve 220b will open and the full main vacuum will be provided to the third suction segment 213. After the third section segment 213 is tightly covered by a portion of the wafer, the third check valve 220c opens and the full vacuum is then provided to the outermost suction segment 214 of the top face 210 of the chuck. This way, a wafer can smoothly be sucked from the inside of the top face 210 of the chuck towards the outside.

Finally, when the wafer is completely held by each of the suction segments, an additional vacuum is applied by the further inlet 219 of the cascade connection so as provide sufficient low pressure to each of the suction segments in order to stably hold the wafer.

This procedure is further illustrated by FIG. 3. First, a wafer 36 covers the top face 39 of the chuck according to shape 36a, i.e., the wafer 36 touches the top face 39 only in the area around the centre of the top face 39. Then, the cascade connection 38 is supplied with a main vacuum 30. First, a vacuum 31a is provided to the suction segment 32a around the centre of the top face 39. Accordingly, the wafer 36 is tightly sucked in the area of the suction segment 32a such that fluid can no longer be sucked within this area. The wafer is then in a state of the shape 36b. Consequently, check valve 33a opens and a vacuum 31b is provided to the second suction segment 32b. Then, fluid is sucked in the area of the suction segment 32b and the wafer is pulled towards the second suction segment 32b until the wafer covers suction segment 32b and seals it tightly. Then, the wafer is in a state of the shape 36c. Subsequently, the procedure repeats by opening check valve 32b and sucking the wafer in the area of suction segment 32c, and finally by opening check valve 32c and sucking the wafer in the area of suction segment 32d. Then, the wafer is completely sucked by the check valve and in a flat state 36d.

However, every check valve causes a decay of the (absolute) value of the (low) pressure in the vacuum channel 41. FIG. 4 shows a situation, wherein a wafer 45 is completely sucked by the chuck such that any of the suction segments 42a, 42b, 42c, and 42d is tightly sealed by the wafer 45. Then, at the first suction segment 42a, which is directly connected to the main vacuum supply, there is a low pressure of minus 1 bar. However, at the second suction segment 42b, which is connected to the main vacuum via the first check valve 42a, the (absolute) value of the low pressure is reduced and amounts to only −0.7 bar. At the third suction segment 42c, (the absolute value of) the low pressure has again reduced and amounts to −0.5 bar, due to the fact that the third suction segment 42c is connected to the main vacuum supply via two check valves 42a and 42b. Finally, at the last (outer) suction segment 42d, which is connected to the main vacuum supply via three check valves 42a to 42c, the absolute value of the low pressure amounts only to ¼ of the corresponding value at the inner suction segment 42a, i.e. the low pressure at the suction segment 42d is −0.25 bar. Consequently, the pressure by which the wafer 45 is held on the top face of the chuck is not constant over the top face, but decreases from the centre to the edge of the chuck. Thus, holding the wafer 45 may be less stable in the outer regions of the top face of the chuck (suction segment 42d) then in the inner regions of the top face (suction segment 42a).

In order to stabilize the wafer 55 on the top face of the chuck 56, an additional vacuum 52, 53 can be applied to the cascade connection. FIG. 5 again shows a situation, wherein the wafer 55 is already completely sucked by the chuck and seals tightly all suction segments on the top face 56. A main vacuum 50 is supplied to the cascade connection and distributed to each of the suction segments 57a, 57b, 57c, and 57d by the vacuums 51a, 51b, 51c, and 51d. As explained above in the context of FIG. 4, the strongest vacuum 51a is provided to the inner suction segment 57a. Towards the edge of the top face 56 of the chuck, the vacuum provided to the suction segments 57b to 57d decreases. In order to compensate for this effect, an additional vacuum can be applied. For example, an additional vacuum 52 can be applied to the cascade connection at the side opposite to the main vacuum supply 50. Then, the outer suction segment 57d is connected directly (i.e., not via a check valve) to the additional vacuum 52, the strength of which can be chosen so as to provide for a sufficient low pressure at the suction segment 57d in order to stably hold the wafer 55 in this area. Furthermore, an additional vacuum 53 can additionally applied to each of the remaining suction segments 57a to 57c or to areas located between the suction segments. Then, a constant and sufficient low pressure is applied to each of the suction segments, and the wafer 55 is stably held by the top face 56 of the chuck.

This situation is also illustrated by FIG. 6. In a manner similar to the situations described above, a main vacuum 61 and an additional vacuum 62 is applied to the cascade connection 63. As illustrated by the gauges sketched below the suction segments 66a to 66d, the vacuum (low pressure) applied to any of these suction segments 66a to 66d amounts to −1 bar.

FIG. 7 shows an embodiment of a circuit for measuring, at which of the suction segments 71a, 71b, and 71c a wafer most tightly covers the respective suction segment. Therefore, an auxiliary vacuum 76 is provided that is branched off from the main vacuum 77 via a throttle 75. Via check valves 73a to 73c, the auxiliary vacuum is applied to each of the suction segments 71a to 71c. The low pressure at each of the suction segments is then measured by measurement means 72a, 72b, and 72c. Subsequently, it is determined, at which of the suction segments the absolute value of the low pressure is maximal. Then, the respective switch 74a, 74b, or 74c is operated in order to provide the main vacuum 77 to the respective suction segment. When the wafer has been sucked at this suction segment, the procedure will be repeated, i.e., it is again checked at which of the (remaining) suction segments the absolute value of the low pressure has a maximum value, and the main vacuum is applied to this suction segment by switching on the respective switch.

FIG. 8 shows a possible partitioning of the top face 80 of a chuck according to one embodiment of the invention. The top face 80 is formed as a circular disc. By the partitioning, the top face 80 is divided into a plurality of suction segments. For example, around the centre point of the disc, a circular suction segment 81 is arranged. Likewise centered around the centre point of the top face 80, a larger circular area is arranged, which is subdivided along three straight lines having a radial orientation relative to the centre point of the top face 80 that divide said larger circular area into three equally sized suction segments 82a, 82b, and 82c. Of course, the area of these suction segments does not overlap with the area of the inner suction segment 81; in other words, the area of the inner suction segment 81 is cropped from the areas of the suction segments 82a to 82c. A further area is located between the suction segments 82a to 82c and the radius of the edge of the top face 80 of the chuck. This area is subdivided into four equally sized suction segments 83a, 83b, 83c, and 83d by four straight lines radially orientated relative to the centre point of the top face 80.

FIG. 9 shows a photograph of the embodiment of the top face already shown in FIGS. 1 and 2 and that has been already discussed in that context. In the photograph, at a plurality of the positions in the grooves 92, through holes 91 are recognizable that connect the grooves 92 with inlets (not shown) arranged under the top face 93 of the chuck for supplying vacuum as described in the context of FIGS. 1 and 2.

FIG. 10 shows a photograph of the bottom face 100 of one embodiment of the chuck. A main vacuum channel 101 is arranged spirally on the bottom face 100. The vacuum channel 101 is divided into several portions that are separated from each other by check valves 102. The assembly forms one embodiment of the cascade connection as illustrated and described in the context of FIGS. 2 and 3.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below.

Furthermore, in the claims the word “comprising” does not exclude other elements or steps, and the indefinite article “a” or “an” does not exclude a plurality. A single unit may fulfil the functions of several features recited in the claims. The terms “essentially”, “about”, “approximately” and the like in connection with an attribute or a value particularly also define exactly the attribute or exactly the value, respectively. Any reference signs in the claims should not be construed as limiting the scope.

1. A chuck for suction and holding a wafer, comprising a flat top face being subdivided into several suction segments, wherein the suction segments are each configured for suctioning a fluid; and a bottom face,
wherein:
the top face is configured for being brought, within a fluid, into vicinity with a wafer such that two or more of the suction segments are covered, at least loosely covered, by the wafer; and
each of the suction segments is separately activatable, wherein
a cascade connection is provided which has an inlet configured for being supplied with vacuum and which is connected to the suction segments in order to separately activate the suction segments wherein the cascade connection is configured to apply an additional vacuum to stably hold the wafer.

2. The chuck according to claim 1, wherein the chuck further comprises:
a means, preferably a throttle, configured for supplying each of the suction segments with an auxiliary vacuum;
a means, preferably comprising at least one pressure detection means or at least one flow rate detection means, configured for measuring, at any one of the suction segments, the low pressure or the flow rate of the volume flow of fluid sucked in by the respective suction segment when being supplied with the auxiliary vacuum; and
a means, preferably a mechanical and/or electric means connected to each of said means configured for measuring the low pressure or the flow rate, configured for determining at which of the suction segments, when supplied with the auxiliary vacuum, is measured a maximum absolute value of the low pressure or a minimum volume flow of the fluid.

3. The chuck according to claim 1, wherein:
the top face of the chuck is a disc;
an inner suction segment is arranged around the center point of the top face;
further suction segments are arranged as rings around the inner suction segment; and
wherein preferably each of the suction segments is separated from the other suction segments.

4. The chuck according to claim 3, wherein each of the suction segments comprises a system of interconnected grooves arranged on the top face of the chuck, and wherein preferably each system of interconnected grooves comprises one or more grooves shaped as concentric circles around the center point of the top face.

5. The chuck according to claim 1, wherein the several suction segments are arranged on the top face such that a virtual spiral-shaped path originated in a point within one of the suction segments and looping to the edge of the top face proceeds on the top face, wherein the path enters and/or leaves any one of the suction segments one and only one time.

6. The chuck according to claim 1,
wherein each suction segment is connected to a main vacuum distribution means being arranged at the bottom face of the chuck and configured for supplying each of the suction segments with vacuum; and
wherein the supply of each of the suction segments, possibly with the exception of one suction segment, is controllable by a valve.

7. The chuck according to claim 6,
wherein:
the several suction segments are arranged on the top face such that a virtual spiral-shaped path originated in a point within one of the suction segments and looping to the edge of the top face proceeds on the top face, wherein the path enters and/or leaves any one of the suction segments one and only one time;
the main vacuum supply means comprises a main vacuum channel having an inlet configured for being supplied with vacuum;
each of the suction segments is connected to the main vacuum channel by a side conduit having a junction to the main vacuum channel;
between any two adjacent junctions, a valve is arranged inside the main vacuum channel such that the main vacuum channel exhibits several sections separated by said valves;
the side conduits are arranged such that any two adjacent sections of the main vacuum channel are connected to neighbored suction segments.

8. The chuck according to claim 7, wherein each of said valves is a check valve, for example one of a ball check valve, a diaphragm check valve, a swing check valve, a tilting disc check valve, a stop check valve, a lift check valve, an in-line check valve, or a duckbill valve;
wherein each of the check valves is configured such that it automatically opens if the absolute value of the low pressure in the section next to the check valve in the direction towards the inlet of the main vacuum channel is equal to or greater than a predefined value; and
wherein preferably each of the check valves is configured such that it opens only if the absolute value of the low pressure in the section next to the check valve in the direction towards the inlet of the main vacuum channel is value corresponding to a state, wherein the wafer tightly touches the suction segment connected to the section next to the check valve in the direction towards the inlet.

9. A method for suction and holding a wafer by a chuck,
wherein the chuck comprises:
a flat top face being subdivided into several suction segments, wherein the suction segments are each configured for suctioning a fluid;
a bottom face; and
a cascade connection having an inlet configured for being supplied with vacuum and being connected to the suction segments in order to separately activate the suction segments wherein the cascade connection is configured to apply an additional vacuum to stably hold the wafer;
the method comprising the steps:
(9a) bringing, within a fluid, wafer and top face of the chuck into vicinity such that two or more of the suction segments are covered, at least loosely covered, by the wafer;
(9b) choosing, from the suction segments not yet been activated, a suction segment having a minimal distance to the wafer;
(9c) activating the suction segment chosen in step (9b);
(9d) once the wafer in the area of the last-activated suction segment tightly touches the top face of the chuck and as long as at least one suction segment is not yet activated:
repeating steps (9b) to (9d).

10. The method of claim 9, wherein step (9b) of choosing a suction segment having a minimal distance to the wafer comprises the steps of:
(10a) measuring the distance of each of the suction segments to the surface of the wafer facing the respective suction segment;
(10b) determining, from the suction segments not yet activated, a suction segment having a minimal distance to the wafer.

11. The method of claim 10, wherein step (10a) of measuring the distance comprises the steps of:
(11a) supplying, preferably by a throttle, each of the suction segments not yet been activated with an auxiliary vacuum;
(11b) measuring, for each of the suction segments supplied with the auxiliary vacuum in step (11a), the low pressure or the flow rate of the volume flow of the fluid sucked in, preferably by a pressure detection means or a flow rate detection means; and
wherein step (10b) of determining a minimal distance comprises the steps of:
(11c) determining, preferably by a mechanical and/or electric means connected to each of the pressure detection means or each of the flow rate detection means, at which of the suction segments supplied with the auxiliary vacuum is measured a maximum absolute value of the low pressure or a minimum volume flow of the fluid.

12. The method of claim 9, wherein the sequence of suction segments chosen in step (9b) is predefined according to a known shape of the wafer.

13. The method of claim 9, wherein:
the top face of the chuck is a disc;
an inner suction segment is arranged around the center point of the top face; further suction segments are arranged as rings around the inner suction segment; and
wherein preferably each of the suction segments is separated from the other suction segments.

14. The method of claim 13, wherein each of the suction segments comprises a system of interconnected grooves arranged on the top face of the chuck, and wherein preferably each system of interconnected grooves comprises one or more grooves shaped as concentric circles around the center point of the top face.

15. The method of claim 12, wherein the several suction segments are arranged on the top face such that a virtual spiral-shaped path originated in a point within one of the suction segments and looping to the edge of the top face proceeds on the top face, wherein the path enters and/or leaves any one of the suction segments one and only one time; and
wherein the sequence of suction segments chosen in step (9b) follows the virtual spiral-shaped path, wherein the first suction segment is the suction segment with the origin of the virtual spiral-shaped path.

16. The method of claim 9,
wherein each suction segment is connected to a main vacuum distribution means being arranged at the bottom face of the chuck and configured for supplying each of the suction segments with vacuum;
wherein the supply of each of the suction segments, possibly with the exception of one suction segment, is controllable by a valve;
wherein the method comprises the step of:
(16a) supplying the main vacuum distribution means with vacuum, this step being started before or together with step (9c) and executed as long as the wafer is to be held by the chuck; and
wherein step (9c) of activating a suction segment comprises the step of:
(16b) if the suction segment is controllable by a valve: opening the valve being configured to control the respective suction segment,
otherwise: starting step (16a).

17. The method of claim 16,
wherein:
the sequence of suction segments chosen in step (9b) is predefined according to a known shape of the wafer:
the main vacuum supply means comprises a main vacuum channel having an inlet configured for being supplied with vacuum;
each of the suction segments is connected to the main vacuum channel by a side conduit having a junction to the main vacuum channel;
between any two adjacent junctions, a valve is arranged inside the main vacuum channel such that the main vacuum channel exhibits several sections separated by said valves;
the side conduits are arranged such that any two adjacent sections of the main vacuum channel are connected to neighbored suction segments; and
wherein step (9b) of choosing a suction segment comprises:
if step (9b) is executed the first time during the performance of the method: choosing the suction segment connected to the section of the of main vacuum channel next to the inlet;
otherwise: choosing the suction segment connected to the section of the main vacuum channel next to the section connected to the suction segment previously chosen in step (9b).

18. The method of claim 17, wherein each of said valves is a check valve, for example one of a ball check valve, a diaphragm check valve, a swing check valve, a tilting disc check valve, a stop check valve, a lift check valve, an in-line check valve, or a duckbill valve;
wherein each of the check valves is configured such that it automatically opens if the absolute value of the low pressure in the section next to the check valve in the direction towards the inlet of the main vacuum channel is equal to or greater than a predefined value; and
wherein preferably each of the check valves is configured such that it opens only if the absolute value of the low pressure in the section next to the check valve in the direction towards the inlet of the main vacuum channel is value corresponding to a state, wherein the wafer tightly touches the suction segment connected to the section next to the check valve in the direction towards the inlet.

19. The method of claim 17, comprising the further step of:
(19a) upon the wafer completely being held by the chuck: supplying the main vacuum channel with an additional vacuum from the side opposite to the inlet.
